(19) United States
(12) Patent Application Publication
(10) Pub. No.: US 2023/0021980 A1
(43) Pub. Date: Jan. 26, 2023

(54) CLEANING MACHINE AND CLEANING METHOD OF PHOTOMASK PELLICLE

(71) Applicant: CHANGXIN MEMORY TECHNOLOGIES, INC., Hefei City (CN)

(72) Inventor: Fei SUN, Hefei (CN)

(21) Appl. No.: 17/515,819

(22) Filed: Nov. 1, 2021

Related U.S. Application Data
(63) Continuation of application No. PCT/CN2021/117030, filed on Sep. 7, 2021.

(30) Foreign Application Priority Data
Jul. 19, 2021 (CN) 202110812571.5

(51) Int. Cl. G03F 7/20; B08B 5/02; B08B 3/10; B08B 3/08; B08B 7/04

(52) U.S. Cl. CPC G03F 7/70925; G03F 7/70983; B08B 5/02; B08B 3/10; B08B 3/08; B08B 7/04

(57) ABSTRACT

A cleaning machine and a cleaning method for a photomask pellicle are provided. The cleaning machine at least includes: an air knife and a cleaning device. The air knife is configured to blow away contamination particles on the surface of the photomask pellicle. The cleaning device is configured to spray cleaning liquid to the surface of the photomask pellicle, to weather the contamination particles failed to be blown away by the air knife through the volatilization of the cleaning liquid. The air knife is also configured to blow away the weathered contamination particles.

### CROSS-REFERENCE TO RELATED APPLICATION

This is a continuation application of International Patent Application No. PCT/CN2021/117030, filed on Sep. 7, 2021, which claims the priority of Chinese Patent Application Serial No. 202110812571.5, filed on Jul. 19, 2021 and titled “Cleaning Machine and Cleaning Method of Photomask Pellicle”. The disclosures of International Patent Application No. PCT/CN2021/117030 and Chinese Patent Application Serial No. 202110812571.5 are incorporated by reference herein in their entireties.

### TECHNICAL FIELD

The embodiments of the disclosure relate to, but are not limited to, a cleaning machine and a method for cleaning a photomask pellicle.

### BACKGROUND

In a semiconductor manufacturing process, due to machine factors or human factors, a photomask pellicle will inevitably be contaminated by particles that exceed the specifications. Subsequent product manufacturing processes can only be carried out after these particles are removed in time.

At present, an air knife has been used in the factory to blow away the particles on the surface of the pellicle by means of an air blast. However, some particles are firmly adhered on the surface of the pellicle. When the particles are difficult to blow away with an air knife of a machine, the pellicle must be sent back to the photomask factory for emergency repair, which leads to the suspension of product line and the delay of product delivery.

### SUMMARY

In accordance with a first aspect of the present disclosure, there is provided a cleaning machine for a photomask pellicle, at least including: an air knife and a cleaning device. The air knife is configured to blow away contamination particles on the surface of the photomask pellicle. The cleaning device is configured to spray cleaning liquid to the surface of the photomask pellicle, to weather (air-slake) the contamination particles failed to be blown away by the air knife through the volatilization of the cleaning liquid. The air knife is also configured to blow away the weathered contamination particles.

In accordance with a second aspect of the present disclosure, there is provided a method of cleaning a photomask pellicle. The method of cleaning a photomask pellicle is applied to the above cleaning machine for a photomask pellicle. The cleaning machine at least includes: an air knife and a cleaning device. The method includes: blowing away contamination particles on the surface of the photomask pellicle by the air knife; spraying cleaning liquid to the surface of the photomask pellicle by the cleaning device, to weather the contamination particles failed to be blown away by the air knife through the volatilization of the cleaning liquid; and blowing away the weathered contamination particles by the air knife.

### BRIEF DESCRIPTION OF THE DRAWINGS

In the drawings (which are not to precise scale), similar reference numerals can describe similar parts in different diagrams. The similar reference numerals can represent different examples of the similar parts. The drawings almost show every embodiment discussed herein with examples rather than in a limiting manner.

FIG. 1A is a schematic view showing a pellicle in an example, on the surface of which particles are deposited.

FIG. 1B is a schematic view showing the manner for removing particles on the surface of the pellicle in an example.

FIG. 2 is a schematic view of a cleaning machine for a photomask pellicle provided in the embodiments of the disclosure.

FIG. 3A is another schematic view of a cleaning machine for a photomask pellicle provided in the embodiments of the disclosure.

FIG. 3B is a schematic view of weathering of the contamination particles by cleaning liquid provided in the embodiments of the disclosure.

FIG. 4A is a schematic view of a cleaning machine for a photomask pellicle provided in the embodiments of the disclosure.

FIG. 4B is a graph of air velocity change of an air knife obtained in real time by an air knife monitoring device provided in the embodiments of the disclosure.

FIG. 5 is a schematic flow diagram of a method of cleaning a photomask pellicle provided in the embodiments of the disclosure.

### DETAILED DESCRIPTION

The exemplary embodiments disclosed in the disclosure will be described in more detail below with reference to the drawings. Although the exemplary embodiments of the disclosure are shown in the drawings, it should be understood that the disclosure may be implemented in various forms and should not be limited by the specific embodiments set forth herein. On the contrary, these embodiments are provided for a more thorough understanding of the disclosure, and to fully convey the scope of the disclosure to those skilled in the art.

In the following description, a lot of specific details are given in order to provide a more thorough understanding of the disclosure. However, it is obvious to those skilled in the art that the disclosure may be implemented without one or more of these details. In other examples, in order to avoid confusion with the disclosure, some technical features known in the art are not described. That is, all the features of actual embodiments are not described here, and known functions and structures are not described in detail.

In the drawings, the sizes of layers, regions and elements and the relative sizes thereof may be exaggerated for clarity. The same reference numerals represent the same elements throughout.

It should be understood that when an element or a layer is referred to as being “on”, “adjacent to”, “connected to” or “coupled to” other elements or layers, it may be directly on, adjacent to, connected to or coupled to other elements or layers, or there may be intermediate elements or layers. On the contrary, when an element is referred to as being “directly on”, “directly adjacent to”, “directly connected to” or “directly coupled to” other elements or layers, there are no intermediate elements or layers. It should be understood that although the terms first, second, third, etc. may be used to describe various elements, components, regions, layers, and/or parts, these elements, components, regions, layers, and/or parts should not be limited by these terms. These terms are used merely to distinguish one element, component, region, layer, or part from another element, component, region, layer, or part. Therefore, a first element, component, region, layer, or part discussed below may be represented as a second element, component, region, layer, or part without departing from the teachings of the disclosure. When the second element, component, region, layer, or part is discussed, it does not mean that the first element, component, region, layer, or part is necessarily present in the disclosure.

The purpose of the terms used herein is only to describe specific embodiments and not as a limitation of the disclosure. As used herein, the singular forms “a/an”, “one”, and “the/this” are also intended to include the plural forms as well, unless the context clearly dictates otherwise. It should also be understood that when the terms “composed of” and/or “including” are used in this specification, the presence of the features, integers, steps, operations, elements, and/or components is determined, but the presence or addition of one or more other features, integers, steps, operations, elements, components, and/or groups is also possible. As used herein, the term “and/or” includes any and all combinations of the associated listed items.

Before the cleaning machine for a photomask pellicle provided in the embodiments of the disclosure is described in detail, a cleaning machine and a removal process of particles in the related art will be described first.

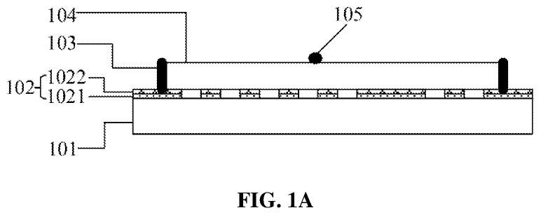

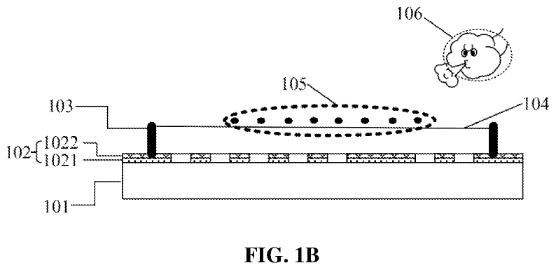

FIG. 1A is a schematic view showing a pellicle in an example, on the surface of which particles are deposited. As shown in FIG. 1A, a photomask includes quartz glass 101, a photomask pattern 102 formed on the surface of the quartz glass 101, an aluminum frame 103 arranged on the surface of the photomask pattern, and a pellicle 104 fixed on the surface of the aluminum frame 103. The photomask pattern 102 includes chromium 1021 and photosensitive resist 1022. In the related art, the photosensitive resist 1022 is exposed through electronic laser equipment according to a designed circuit pattern, and the exposed region will be developed to form the photomask pattern 102 on the chromium metal 1021. There is a certain gap between the pellicle 104 and the photomask pattern 102, and the pellicle 104 is configured to prevent a particle 105 from directly falling on the photomask pattern 102 and damaging the photomask pattern 102.

At present, an air knife has been used in the factory to blow away the particles on the surface of the pellicle by means of an air blast. However, some particles are firmly adhered on the surface of the pellicle. When the particles are difficult to blow away with an air knife of a machine, it will have a serious impact on the exposure. Therefore, the pellicle must be sent back to the photomask factory for emergency repair, which leads to the suspension of product line and the delay of product delivery.

In addition, it is found that an output port of an air knife of a photomask cleaning machine is unstable, so that when the particles on the surface of the pellicle are blown away by the air knife, the photomask pellicle is easily damaged, resulting in damage to the photomask pattern and scrapping of the entire photomask. As shown in FIG. 1B, when the strength of air at the output port of an air knife 106 of a machine is too large, the pellicle 104 will be damaged. In the related art, the damage of the pellicle will further cause the damage of the photomask pattern.

Based on the above problems in the related art, the embodiments of the disclosure provide a cleaning machine and a method of cleaning a photomask pellicle, which can remove the contamination particles firmly adhered on the surface of the photomask pellicle, does not affect the production processes and delivery date of products, and does not cause the damage to the photomask pellicle in a cleaning process.

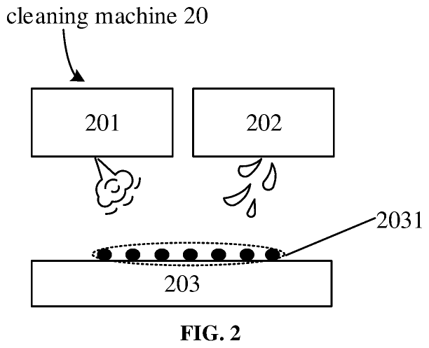

FIG. 2 is a schematic view of a cleaning machine for a photomask pellicle provided in the embodiments of the disclosure. As shown in FIG. 2, a cleaning machine 20 for a photomask pellicle includes an air knife 201 and a cleaning device 202.

The air knife 201 is configured to blow away contamination particles 2031 on the surface of the photomask pellicle 203. The cleaning device 202 is configured to spray cleaning liquid to the surface of the photomask pellicle 203, so as to weather the contamination particles failed to be blown away by the air knife through the volatilization of the cleaning liquid.

In the embodiments of the disclosure, the air knife may be a strong air type air knife, a curved air knife or an ionic air knife.

In some embodiments, the cleaning device 202 at least includes: a nozzle, a liquid discharge pipeline and a liquid storage tank. One end of the liquid discharge pipeline is connected with the nozzle, and the other end of the liquid discharge pipeline is connected with the liquid storage tank. The liquid storage tank is configured to store the cleaning liquid which will be sprayed through the liquid discharge pipeline and the nozzle. Here, the nozzle may be a hollow cone nozzle, a solid cone nozzle, a square nozzle, a rectangular nozzle, an oval nozzle or a fan nozzle, and the liquid storage tank may be a liquid storage container of any shape.

The cleaning liquid in the embodiments of the disclosure may be a cleaning liquid which has volatility and can weather contamination particles. For example, the cleaning liquid may be alcohol or other similar cleaning liquids. It should be noted that since the photomask pellicle is a layer of transparent film, the cleaning liquid should not cause corrosion or other impacts on the photomask pellicle in the cleaning process.

In some embodiments, the air knife 201 is also configured to blow away the weathered contamination particles.

In the cleaning machine for the photomask pellicle provided in the embodiments of the disclosure, since the cleaning device in the cleaning machine can weather the contamination particles failed to be blown away by the air knife, the cleaning machine provided in the embodiments of the disclosure can remove the contamination particles firmly adhered to the photomask pellicle, without affecting the production processes and delivery date of products.

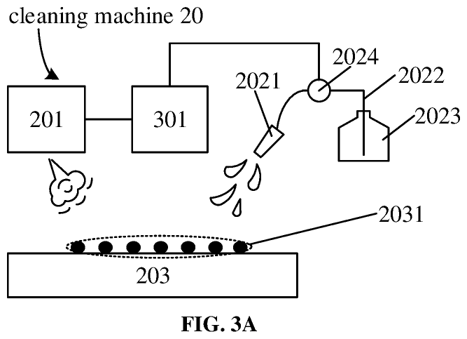

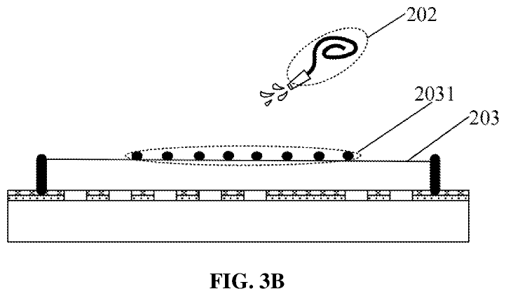

FIG. 3A is another schematic view of a cleaning machine for a photomask pellicle provided in the embodiments of the disclosure. As shown in FIG. 3A, the cleaning machine 20 of the photomask pellicle includes: an air knife 201, a cleaning device and a controller 301.

The controller 301 is connected with the air knife 201 and the cleaning device. The controller 301 is configured to control the air knife 201 to blow away the contamination particles 2031 on the surface of the photomask pellicle 203, and control the cleaning device to spray the cleaning liquid to the surface of the photomask pellicle 203 if there are contamination particles failed to be blown away by the air knife 201 on the surface of the photomask pellicle 203, so as to weather the contamination particles failed to be blown away by the air knife through the volatilization of the cleaning liquid.

In the embodiments of the disclosure, the controller may be a Programmable Logic Controller (PLC).

In the embodiments of the disclosure, the cleaning device includes a nozzle 2021, a liquid discharge pipeline 2022, a liquid storage tank 2023 and a liquid conveying device 2024. One end of the liquid discharge pipeline 2022 is connected with the nozzle 2021, and the other end of the liquid discharge pipeline 2022 is connected with the liquid storage tank 2023. The liquid storage tank 2023 is configured to store the cleaning liquid, to be sprayed through the liquid discharge pipeline 2022 and the nozzle 2021. The liquid conveying device 2024 is arranged in the liquid discharge pipeline 2022, the liquid conveying device 2024 is connected with the controller 301, and the liquid conveying device 2024 is configured to convey the cleaning liquid from the liquid storage tank 2023 to the nozzle 2021 under the control of the controller 301.

In some embodiments, the liquid conveying device 2024 may be a power pump, a gear pump, a diaphragm pump or a peristaltic pump.

In some embodiments, the cleaning device may further include a flow meter arranged in the liquid discharge pipeline (not shown in FIG. 3A). The flow meter is connected with the controller, and the flow meter is configured to count the aggregate flow of the cleaning liquid flowing through the liquid discharge pipeline. The controller is configured to determine whether the aggregate flow is greater than a preset flow value, and output alarm information responsive to the aggregate flow being greater than the preset flow value.

In the embodiments of the disclosure, the preset flow value may be slightly smaller than the volume of the liquid storage tank. When the controller determines that the aggregate flow value of the cleaning liquid flowing through the liquid discharge pipeline exceeds the preset flow value, it indicates that the cleaning liquid in the liquid storage tank is about to be used up, and at this time, the controller outputs alarm information to notify operator to replenish the cleaning liquid in time, therefore, the whole cleaning process can be made sustainable.

In the embodiments of the disclosure, the cleaning liquid may be alcohol or other similar organic cleaning agents.

In some embodiments, the controller 301 is also configured to control the air knife 201 to blow away the weathered contamination particles.

FIG. 3B is a schematic view of weathering contamination particles by cleaning liquid provided in the embodiments of the disclosure. As shown in FIG. 3B, if there are contamination particles failed to be blown away by the air knife on the surface of the photomask pellicle 203, the controller controls the cleaning device 202 to spray the cleaning liquid (such as alcohol) to the surface of the photomask pellicle 203, so as to weather the contamination particles through the volatilization of the cleaning liquid, and then, the controller controls the air knife 201 to blow away the weathered contamination particles.

In the cleaning machine for the photomask pellicle provided in the embodiments of the disclosure, since the cleaning device in the cleaning machine can weather the contamination particles failed to be blown away by the air knife, the cleaning machine provided in the embodiments of the disclosure can remove the contamination particles firmly adhered to the photomask pellicle, without affecting the production processes and delivery date of products.

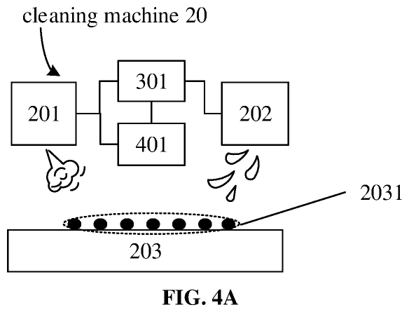

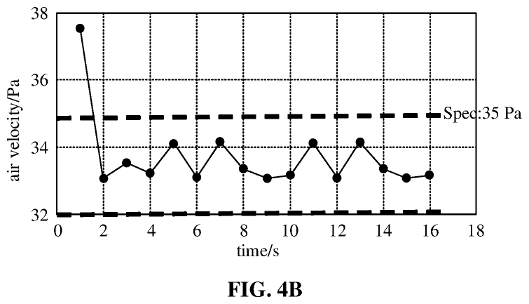

FIG. 4A is another schematic view of a cleaning machine for a photomask pellicle provided in the embodiments of the disclosure. As shown in FIG. 4A, the cleaning machine 20 of the photomask pellicle includes: an air knife 201, a cleaning device 202, a controller 301 and an air knife monitoring device 401.

The controller 301 is connected with the air knife 201 and the cleaning device 202. The controller 301 is configured to control the air knife 201 to blow away the contamination particles 2031 on the surface of the photomask pellicle 203, and control the cleaning device 202 to spray the cleaning liquid to the surface of the photomask pellicle 203 if there are contamination particles failed to be blown away by the air knife 201 on the surface of the photomask pellicle 203, so as to weather the contamination particles not blown away by the air knife through the volatilization of the cleaning liquid. The air knife monitoring device 401 is connected with the air knife 201 and the controller 301, and the air knife monitoring device 401 is configured to monitor the output parameter of the air knife 201 in real time. The controller 301 is also configured to control the air knife 201 to stop working responsive to the output parameter of the air knife 201 being greater than a preset parameter value.

In the embodiments of the disclosure, the output parameter of the air knife 201 includes air pressure, air velocity and air volume. The preset parameter value includes a preset air pressure value, a preset air velocity value and a preset air volume value. The preset air pressure value, the preset air velocity value or the preset air volume value is the parameter value ensuring that photomask pellicle will not be damaged.

In some embodiments, the air knife monitoring device 401 may be any one of an air pressure flow meter, an air velocity flow meter, an air volume flow meter, an air pressure sensor, an air velocity sensor or an air volume sensor.

In some embodiments, the controller is also configured to output prompting information responsive to the output parameter of the air knife 201 being greater than the preset parameter value. Here, the prompting information is used to prompt the operator that the output parameter of the air knife is unstable.

In the embodiments of the disclosure, a machine air velocity monitoring system (that is, the air knife monitoring device) is additionally provided to avoid the problem of film damage caused by an unstable output of a machine. FIG. 4B is a graph of air velocity change of an air knife obtained in real time by an air knife monitoring device provided in the embodiments of the disclosure. When the air knife works (that is, blows air to the surface of the photomask pellicle), the air knife monitoring device obtains the air velocity of the air knife in real time (per second), which can form an air velocity curve as shown in FIG. 4B. When the air velocity of the air knife exceeds the preset air velocity value Spec, such as 35 Pa, the air knife will be immediately stopped and an alarm will be sent.

In the cleaning machine provided in the embodiments of the disclosure, since the cleaning device in the cleaning machine can weather the contamination particles failed to be blown away by the air knife, the cleaning machine provided in the embodiments of the disclosure can remove the contamination particles firmly adhered to the photomask pellicle, without affecting the production processes and delivery date of products. Moreover, the cleaning machine provided in the embodiments of the disclosure is provided with the air knife monitoring device which can monitor the output parameter of the air knife in real time, so as to avoid the pellicle damage caused by the unstable output parameter of the air knife.

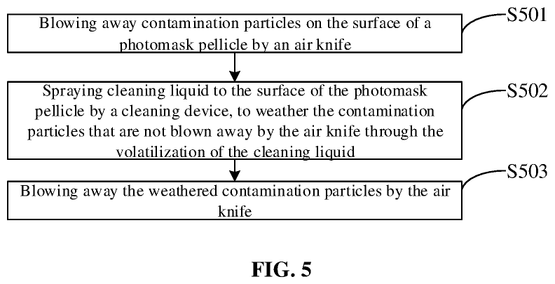

In addition, the embodiments of the disclosure further provide a method of cleaning a photomask pellicle. The method of cleaning a photomask pellicle is applied to the cleaning machine for a photomask pellicle provided in the above embodiments. The cleaning machine at least includes an air knife and a cleaning device. FIG. 5 is a schematic flow diagram of a method of cleaning a photomask pellicle provided in the embodiments of the disclosure. As shown in FIG. 5, the method includes the following operations.

At S501, contamination particles on the surface of the photomask pellicle are blown away by the air knife.

At S502, cleaning liquid is sprayed to the surface of the photomask pellicle by the cleaning device, to weather the contamination particles failed to be blown away by the air knife through the volatilization of the cleaning liquid.

In the embodiments of the disclosure, the cleaning device may include: a nozzle, a liquid discharge pipeline and a liquid storage tank. One end of the liquid discharge pipeline is connected with the nozzle, and the other end of the liquid discharge pipeline is connected with the liquid storage tank. The liquid storage tank is configured to store the cleaning liquid to be sprayed through the liquid discharge pipeline and the nozzle.

In other embodiments, the cleaning device may further include a liquid conveying device and a flow meter arranged in the liquid discharge pipeline.

In the embodiments of the disclosure, the cleaning liquid may be alcohol or other similar cleaning agents. It should be noted that the cleaning liquid in the embodiments of the disclosure should have volatility and the effect of weathering contamination particles, and does not cause corrosion or other impacts on the photomask pellicle.

At S503, the weathered contamination particles are blown away by the air knife.

In some embodiments, the cleaning machine further includes a controller. The controller is connected with the air knife and the cleaning device. The controller is configured to control the air knife to blow away the contamination particles on the surface of the photomask pellicle, and control the cleaning device to spray the cleaning liquid to the surface of the photomask pellicle if there are contamination particles failed to be blown away by the air knife on the surface of the photomask pellicle, so as to weather the contamination particles failed to be blown away by the air knife through the volatilization of the cleaning liquid. The controller is also configured to control the air knife to blow away the weathered contamination particles.

In some embodiments, after the cleaning liquid is sprayed to the contamination particles failed to be blown away by the air knife on the surface of the photomask pellicle through the cleaning device, the cleaning liquid stays for a preset time so as to weather the contamination particles failed to be blown away by the air knife through the volatilization of the cleaning liquid within the preset time. The preset time is at least 3 min. That is, in the embodiments of the disclosure, the controller controls the cleaning device to spray the cleaning liquid to the surface of the photomask pellicle, and after the cleaning liquid stays for a preset time, the controller controls the air knife to blow away the weathered contamination particles.

In some embodiments, before the cleaning liquid is sprayed, the method further includes the following operations.

At S1, an integrated mask detection system of a photoetching machine detects whether there are contamination particles failed to be blown away by the air knife on the surface of the photomask pellicle.

If the integrated mask detection system of the photoetching machine detects that there are contamination particles failed to be blown away by the air knife on the surface of the photomask pellicle, the S502 is performed. At S502, the controller controls the cleaning device to spray the cleaning liquid to the surface of the photomask pellicle. If the integrated mask detection system of the photoetching machine detects that there are no contamination particles failed to be blown away by the air knife on the surface of the photomask pellicle, the cleaning process of the photomask pellicle is ended.

In the embodiments of the disclosure, firstly, the air knife is configured to blow away the contamination particles on the surface of the photomask pellicle; secondly, the integrated mask detection system of the photoetching machine is configured to detect whether there are contamination particles failed to be blown away by the air knife on the surface of the photomask pellicle and send a detection result to the controller; and if the integrated mask detection system detects that there are contamination particles failed to be blown away by the air knife on the surface of the photomask pellicle, the controller controls the cleaning device to spray the cleaning liquid to the surface of the photomask pellicle, to weather the contamination particles failed to be blown away by the air knife through the volatilization of the cleaning liquid; and finally, the air knife is configured to blow away the weathered contamination particles again, thereby completing the whole cleaning process.

In some embodiments, the cleaning machine further includes an air knife monitoring device. The air knife monitoring device is connected with the air knife and the controller. The method further includes the following operations.

At S2, when the contamination particles on the surface of the photomask pellicle are blown away by the air knife, or when the weathered contamination particles are blown away by the air knife, the output parameter of the air knife is monitored in real time by the air knife monitoring device.

In the embodiments of the disclosure, the air knife monitoring device is additionally provided in the cleaning machine. When the air knife is in a working state, the air knife monitoring device monitors the output parameter of the air knife in real time, to avoid the problem of photomask pellicle damage caused by the unstable output parameter of the air knife.

In some embodiments, the output parameter includes air pressure, air velocity and air volume. The air knife monitoring device includes any one of the following: an air pressure flow meter, an air velocity flow meter, an air volume flow meter, an air pressure sensor, an air velocity sensor or an air volume sensor.

At S3, it is determined whether the output parameter is greater than the preset parameter value.

In the embodiments of the disclosure, the preset parameter value includes: a preset air pressure value, a preset air velocity value and a preset air volume value. The preset air pressure value, the preset air velocity value or the preset air volume value is the parameter value ensuring that photomask pellicle will not be damaged.

In some embodiments, the controller determines whether the output parameter is greater than the preset parameter value, then the S4 or S5 is performed responsive to the output parameter being greater than the preset parameter value, and the S6 is performed responsive to the output parameter being less than or equal to the preset parameter value.

At S4, the controller controls the air knife to stop working.

At S5, the controller outputs prompting information.

If the output parameter of the air knife is greater than the preset parameter value, it means that the air knife will damage the photomask pellicle. At this time, the air knife needs to stop working immediately. Or, by sending the prompt information to notify the operator to perform corresponding processing.

At S6, the controller controls the air knife to work normally.

If the output parameter of the air knife is less than or equal to the preset parameter value, it means that the air knife will not damage the photomask pellicle. At this time, the air knife can continue to work normally.

It should be noted that the method of cleaning the photomask pellicle provided in the embodiments of the disclosure is similar to the cleaning machine for the photomask pellicle in the above embodiment. The technical features that are not disclosed in detail in the embodiments of the disclosure can be understood with reference to the above embodiments, and will not be repeated here.

In the method of cleaning the photomask pellicle provided in the embodiments of the disclosure, since the cleaning device can weather the contamination particles failed to be blown away by the air knife, the cleaning method provided in the embodiments of the disclosure can remove the contamination particles firmly adhered to the photomask pellicle, without affecting the production processes and delivery date of products. Moreover, according to the cleaning method provided in the embodiments of the disclosure, the output parameter of the air knife can be monitored in real time by the air knife monitoring device, to avoid the problem of pellicle damage caused by the unstable output parameter of the air knife.

In several embodiments provided by the disclosure, it should be understood that the disclosed device and method may be implemented in non-targeted ways. The embodiments of the described devices are only schematic, for example, partition of the unit is only a logical functional partition, and may have other partition manners in actual applications, for instance: multiple units or components may be combined, or may be integrated to another system, or some features may be neglected, or not executed. In addition, the components shown or discussed are coupled or directly coupled to each other.

The units illustrated as separate components may be, or may not be physically separated, and components displayed as units may be, or may not be physical units, may be located in one place, and may also be distributed to multiple network units; and partial or all units therein may be selected according to actual requirements to realize the aim of the solution of this embodiment.

The features disclosed in several method or device embodiments provided by the disclosure may be combined arbitrarily without conflict to obtain a new method embodiment or device embodiment.

The above descriptions are only some implementation manners of the embodiments of the disclosure, but the protection scope of the embodiments of the disclosure is not limited thereto. Any variations or replacements apparent to those skilled in the art within the technical scope disclosed by the embodiments of the disclosure shall fall within the protection scope of the embodiments of the disclosure. Therefore, the protection scope of the embodiments of the disclosure should be subject to the protection scope of the claims.

1. A cleaning machine for a photomask pellicle, at least comprising: an air knife and a cleaning device, wherein
the air knife is configured to blow away contamination particles on a surface of the photomask pellicle;
the cleaning device is configured to spray cleaning liquid to the surface of the photomask pellicle, to weather the contamination particles failed to be blown away by the air knife through a volatilization of the cleaning liquid; and
the air knife is also configured to blow away weathered contamination particles.

2. The cleaning machine of claim 1, further comprising a controller, wherein
the controller is connected with the air knife and the cleaning device; and
the controller is configured to control the air knife to blow away the contamination particles on the surface of the photomask pellicle, and control the cleaning device to spray the cleaning liquid to the surface of the photomask pellicle responsive to that there are contamination particles failed to be blown away by the air knife on the surface of the photomask pellicle, to weather the contamination particles failed to be blown away by the air knife through the volatilization of the cleaning liquid.

3. The cleaning machine of claim 2, wherein the controller is also configured to control the air knife to blow away the weathered contamination particles.

4. The cleaning machine of claim 1, wherein the cleaning device at least comprises: a nozzle, a liquid discharge pipeline and a liquid storage tank;
one end of the liquid discharge pipeline is connected with the nozzle, and the other end of the liquid discharge pipeline is connected with the liquid storage tank; and
the liquid storage tank is configured to store the cleaning liquid to be sprayed through the liquid discharge pipeline and the nozzle.

5. The cleaning machine of claim 4, wherein the cleaning device further comprises: a liquid conveying device arranged in the liquid discharge pipeline; and
the liquid conveying device is connected with a controller, and the liquid conveying device is configured to convey the cleaning liquid from the liquid storage tank to the nozzle under control of the controller.

6. The cleaning machine of claim 4, wherein the cleaning device further comprises: a flow meter arranged in the liquid discharge pipeline;
the flow meter is connected with a controller, and the flow meter is configured to count an aggregate flow of the cleaning liquid flowing through the liquid discharge pipeline; and
the controller is also configured to output alarm information responsive to the aggregate flow being greater than a preset flow value.

7. The cleaning machine of claim 5, wherein the cleaning liquid comprises alcohol.

8. The cleaning machine of claim 4, further comprising: an air knife monitoring device;
the air knife monitoring device is connected with the air knife and a controller, and the air knife monitoring device is configured to monitor an output parameter of the air knife in real time; and
the controller is also configured to control the air knife to stop working responsive to the output parameter of the air knife being greater than a preset parameter value.

9. The cleaning machine of claim 8, wherein the controller is also configured to output prompting information responsive to the output parameter of the air knife being greater than the preset parameter value.

10. The cleaning machine of claim 8, wherein the output parameter comprises air pressure, air velocity and air volume; the preset parameter value comprises a preset air pressure value, a preset air velocity value and a preset air volume value; and
the preset air pressure value, the preset air velocity value or the preset air volume value is the preset parameter value ensuring that photomask pellicle will not be damaged.

11. The cleaning machine of claim 10, wherein the air knife monitoring device comprises any one of the following: an air pressure flow meter, an air velocity flow meter, an air volume flow meter, an air pressure sensor, an air velocity sensor or an air volume sensor.

12. A method of cleaning a photomask pellicle, wherein the method of cleaning the photomask pellicle is applied to a cleaning machine for a photomask pellicle at least comprising an air knife configured to blow away contamination particles on a surface of the photomask pellicle and a cleaning device configured to spray cleaning liquid to the surface of the photomask pellicle; and the method comprises:
blowing away contamination particles on the surface of the photomask pellicle by the air knife;
spraying cleaning liquid to the surface of the photomask pellicle by the cleaning device, to weather the contamination particles failed to be blown away by the air knife through volatilization of the cleaning liquid; and
blowing away weathered contamination particles by the air knife.

13. The method of cleaning the photomask pellicle of claim 12, wherein after the cleaning liquid is sprayed to the surface of the photomask pellicle by the cleaning device, the cleaning liquid stays for a preset time to weather the contamination particles failed to be blown away by the air knife through volatilization of the cleaning liquid within the preset time,
wherein the preset time is at least 3 min.

14. The method of cleaning the photomask pellicle of claim 12, wherein the cleaning machine further comprises a controller at least connected with the cleaning device; and before spraying the cleaning liquid, the method further comprises:
detecting whether there are contamination particles failed to be blown away by the air knife on the surface of the photomask pellicle by an integrated mask detection system of a photoetching machine; and
responsive to that there are contamination particles failed to be blown away by the air knife on the surface of the photomask pellicle, controlling the cleaning device, by the controller, to spray the cleaning liquid to the surface of the photomask pellicle.

15. The method of cleaning the photomask pellicle of claim 14, wherein the cleaning machine further comprises: an air knife monitoring device connected with the air knife and the controller; and the method further comprises:
when the contamination particles on the surface of the photomask pellicle are blown away by the air knife, or when the weathered contamination particles are blown away by the air knife, monitoring an output parameter of the air knife in real time by the air knife monitoring device; and
responsive to the output parameter being greater than a preset parameter value, controlling the air knife to stop working by the controller.

16. The method of cleaning the photomask pellicle of claim 15, further comprising:
responsive to the output parameter being greater than the preset parameter value, outputting prompting information by the controller.
